(19) United States
(12) Patent Application Publication
(10) Pub. No.: US 2019/0092975 A1
(43) Pub. Date: Mar. 28, 2019

(54) POLISHING COMPOSITION, PRODUCTION METHOD OF POLISHING COMPOSITION, POLISHING METHOD, AND MANUFACTURING METHOD OF SEMICONDUCTOR SUBSTRATE

(71) Applicant: FUJIMI INCORPORATED, Kiyosu-shi (JP)

(72) Inventor: Yu-Ling HSU, Miaoli County (TW)

(73) Assignee: FUJIMI INCORPORATED, Kiyosu-shi (JP)

(21) Appl. No.: 16/133,693

(22) Filed: Sep. 17, 2018

(30) Foreign Application Priority Data
Sep. 26, 2017 (JP) 2017-185459

(51) Int. Cl. C09G 1/02; C09K 3/14; H01L 21/3105

(52) U.S. Cl. CPC C09G 1/02; H01L 21/31053; C09K 3/1436

(57) ABSTRACT

Provided is a polishing composition capable of selectively polishing a second layer with respect to a first layer in an object to be polished including the first layer including a SiO₂ film, and the second layer including at least one selected from the group consisting of SiOC, SiOCH, SiCN and SiC.

The polishing composition includes a surface-modified abrasive grain in which an organic acid is immobilized on a surface thereof, and a dispersing agent, wherein an average primary particle size of the surface-modified abrasive grain is more than 6 nm to less than 35 nm, and pH is 5.0 or less.

### CROSS-REFERENCE TO RELATED APPLICATION

The present application is based on Japanese Patent Application No. 2017-185459 filed on Sep. 26, 2017, and a disclosed content thereof is incorporated herein as a whole by reference.

### BACKGROUND

### 1. Technical Field

The present invention relates to a polishing composition, a production method of a polishing composition, a polishing method, and a manufacturing method of a semiconductor substrate.

### 2. Description of Related Arts

In recent years, along with multilayer wiring on a surface of a semiconductor substrate, a so-called chemical mechanical polishing (CMP) technique of physically polishing and planarizing a semiconductor substrate at the time of manufacturing a device is used. CMP is a method of planarizing a surface of an object to be polished such as a semiconductor substrate by using a polishing composition (slurry) including abrasive grains of silica, alumina, ceria, or the like, an anticorrosive agent, and a surfactant, and specifically, is used in processes such as shallow trench isolation (STI), planarization of an interlayer insulating film (ILD film), formation of a tungsten plug, and formation of a multilayer interconnection including copper and a low dielectric constant film.

In recent years, there has been a demand for controlling a so-called removal rate selectivity, which increases a removal rate of a certain film type and suppresses the removal rate of a certain film type in an object to be polished having two or more layers (see, for example, U.S. Patent Application Publication No. 2015/221521).

### SUMMARY

The present inventors conducted daily research and found that in an object to be polished including a first layer including a SiO₂ film, and a second layer including at least one selected from the group consisting of SiOC, SiOCH, SiCN and SiC, it is desired to selectively polish the second layer with respect to the first layer. In particular, the present inventors found that SiOC and SiO₂ were very close in properties as materials, and thus it was difficult to control a removal rate selectivity.

The present invention has been made in view of the above problem, and has an object of providing a polishing composition capable of selectively polishing a second layer with respect to a first layer in an object to be polished including the first layer including a SiO₂ film, and the second layer including at least one selected from the group consisting of SiOC, SiOCH, SiCN and SiC, a production method of the polishing composition, a polishing method using the polishing composition, and a manufacturing method of a semiconductor substrate using the polishing composition.

A mode for solving the above problem of the present invention is a polishing composition used for polishing an object to be polished having a first layer including a SiO₂ film, and a second layer including at least one selected from the group consisting of SiOC, SiOCH, SiCN and SiC, the polishing composition includes: a surface-modified abrasive grain in which an organic acid is immobilized on a surface thereof; and a dispersing agent, wherein an average primary particle size of the surface-modified abrasive grain is more than 6 nm to less than 35 nm, and pH is 5.0 or less.

### DETAILED DESCRIPTION

Hereinafter, the present invention is described. In addition, the present invention is not limited to embodiments below. In addition, unless specifically stated otherwise, operation and measurement of physical properties, and the like are performed under conditions of room temperature (20° C. to 25° C.)/relative humidity of 40% to 50% RH.

(Polishing Composition)

In an embodiment of the present invention, there is provided a polishing composition used for polishing an object to be polished having a first layer including a SiO₂ film, and a second layer including at least one selected from the group consisting of SiOC, SiOCH, SiCN and SiC, the polishing composition includes: a surface-modified abrasive grain in which an organic acid is immobilized on a surface thereof; and a dispersing agent, wherein an average primary particle size of the surface-modified abrasive grain is more than 6 nm to less than 35 nm, and pH is 5.0 or less. With such a configuration, it is possible to selectively polish the second layer with respect to the first layer in an object to be polished including the first layer including a SiO₂ film, and the second layer including at least one selected from the group consisting of SiOC, SiOCH, SiCN and SiC.

(Surface-Modified Abrasive Grain)

The surface-modified abrasive grain is an abrasive grain formed by immobilizing an organic acid on a surface thereof. In the present invention, if the surface-modified abrasive grain is not used as the abrasive grain, the second layer cannot be selectively polished with respect to the first layer, although the reason is unclear.

Examples of the abrasive grain include metal oxides such as silica, alumina, zirconia, and titania. The abrasive grain may be used alone or in combination of two or more kinds. The kind of abrasive grain is preferably silica. Silica includes fumed silica, colloidal silica, or the like, and in particular, colloidal silica is particularly preferable. By using the colloidal silica, it is possible to reduce scratches occurring in the substrate.

According to an embodiment of the present invention, the organic acid is not particularly limited, but may include sulfonic acid, carboxylic acid, and phosphoric acid, and preferably sulfonic acid or carboxylic acid. In addition, in the abrasive grain in which an organic acid is immobilized on the surface thereof (for example, silica), an acidic group derived from the organic acid (for example, a sulfo group, a carboxyl group, or a phosphoric acid group) is immobilized on the surface of the abrasive grain optionally by a covalent bond via a linker structure. Here, the linker structure means an arbitrary structure interposed between the surface of the abrasive grain and the organic acid. Therefore, in the abrasive grain in which an organic acid is immobilized on the surface thereof, an acidic group derived from the organic acid may be immobilized to the surface of the abrasive grain by a direct covalent bond, or even may be immobilized by the covalent bond via the linker structure.

A method of introducing these organic acids to the surface of abrasive grain (for example, silica) is not particularly limited, but includes a method of introducing a state in which a protective group is bonded to the above-described organic acid group onto the surface of the abrasive grain, and then eliminating the protective group, in addition to a method of introducing a mercapto group, an alkyl group, or the like onto the surface of the abrasive grain and then oxidizing the surface of the abrasive grain with an organic acid such as sulfonic acid and carboxylic acid. In addition, the compound used for introducing the organic acid onto the surface of the abrasive grain preferably includes at least one functional group that can be an organic acid group, and further includes a functional group used for bonding with a hydroxyl group on the surface of the abrasive grain (particularly silica), a functional group introduced for controlling hydrophobicity/hydrophilicity, and a functional group introduced for controlling steric bulkiness.

As a specific synthesis method of silica in which an organic acid is immobilized on the surface thereof, when sulfonic acid which is one type of organic acid is immobilized onto the surface of silica, for example, a method described in “Sulfonic acid-functionalized silica through quantitative oxidation of thiol groups”, Chem. Commun. 246-247 (2003) can be performed.

Specifically, it is possible to obtain silica in which sulfonic acid is immobilized on the surface by coupling a silane coupling agent having a thiol group such as 3-mercaptopropyltrimethoxysilane to silica, and then oxidizing the thiol group with hydrogen peroxide. The sulfonic acid-immobilized colloidal silica of Example of the present invention is also manufactured in a similar manner.

When the carboxylic acid is immobilized on the surface of the silica, for example, a method described in “Novel Silane Coupling Agents Containing a Photo labile 2-Nitrobenzyl Ester for Introduction of a Carboxy Group on the Surface of Silica Gel”, Chemistry Letters, 3, 228-229 (2000) can be performed. Specifically, it is possible to obtain a silica on which carboxylic acid is immobilized on a surface thereof by coupling a silane coupling agent including a photoreactive 2-nitrobenzyl ester to silica, followed by light irradiation.

In the present invention, an average primary particle size of the surface-modified abrasive grain is more than 6 nm to less than 35 nm. When it is 6 nm or less or 35 nm or more, the second layer cannot be selectively polished with respect to the first layer, although the reason is unclear. In an embodiment of the present invention, the lower limit of the average primary particle size of the surface-modified abrasive grain is preferably 8 nm or more, more preferably 9 nm or more, further preferably 10 nm or more, further more preferably 11 nm or more, still more preferably 12 nm or more, and still more preferably 13 nm or more. With the average primary particle size, the desired technical effect of the present invention can be efficiently exhibited. Further, in the polishing composition of the present invention, the upper limit of the average primary particle size of the surface-modified abrasive grain is less than 35 nm, preferably 25 nm or less, more preferably 22 nm or less, further preferably 21 nm or less, further more preferably 20 nm or less, still more preferably 19 nm or less, still more preferably 18 nm or less, still more preferably 17 nm or less, still more preferably 16 nm or less, still more preferably 15 nm or less. With the average primary particle size, the desired technical effect of the present invention can be efficiently exhibited. In addition, the average primary particle size of the surface-modified abrasive grain is measured, for example, based on a BET method using nitrogen gas as an adsorption gas by using a flowable specific surface area automatic measuring apparatus (FlowSorb II 2300 manufactured by Shimadzu Corporation). Specifically, a powder material obtained by drying colloidal silica as a sample at 110° C. and pulverizing is charged into a sample tube, the sample is cooled, nitrogen gas is introduced into the sample tube, and an absorption and desorption isotherm is created by a constant volume method gas adsorption method. In addition, the monomolecular layer adsorption amount is calculated by interpreting a process of transition from monomolecular layer adsorption of the first layer to the multilayer adsorption on the adsorption and desorption isotherm, based on the BET method, and a cross sectional area occupied by one nitrogen gas molecule is further integrated, thereby obtaining a specific surface area BET value (m²/g). From the specific surface area (BET value), the primary particle size is calculated by Equation of primary particle size (nm)=6000/(true density (g/cm³)×BET value (m²/g)). For example, in the case of the silica particle, the primary particle size can be calculated by BET diameter (nm)=2727/BET value (m²/g). Even in the present Example, the average primary particle size of the surface-modified abrasive grain was measured as described above.

In the present invention, an average secondary particle size of the surface-modified abrasive grain is not particularly limited, and is, for example, about 10 to 100 nm, or about 20 to 80 nm, and more preferably 20 to 60 nm. The average secondary particle size can be measured by a dynamic light scattering method represented by, for example, a laser diffraction scattering method.

In the present invention, the upper limit of the content of the surface-modified abrasive grain in the polishing composition is preferably 10 mass % or less, more preferably 5.0 mass % or less, further preferably 4.0 mass % or less, further more preferably 3.0 mass % or less, still more preferably 2.5 mass % or less, still more preferably 2.4 mass % or less, still more preferably 2.3 mass % or less, still more preferably 2.2 mass % or less, still more preferably 2.1 mass % or less, still more preferably 2.0 mass % or less, still more preferably 1.0 mass % or less, still more preferably 0.9 mass % or less, still more preferably 0.8 mass % or less, still more preferably 0.7 mass % or less, still more preferably 0.6 mass % or less, still more preferably 0.5 mass % or less, and still more preferably 0.4 mass % or less. Since the content of the surface-modified abrasive grain has the above-described upper limit, the desired technical effect of the present invention can be more effectively exhibited. In the present invention, the lower limit of the content of the surface-modified abrasive grain in the polishing composition is preferably 0.05 mass % or more, more preferably 0.1 mass % or more, and further more preferably 0.2 mass % or more. Since the content of the surface-modified abrasive grain has such a lower limit, a SiOC removal rate can be achieved.

(Dispersing Agent)

In the polishing composition of the present invention, a dispersing agent is used for dispersing each component constituting the polishing composition. As the dispersing agent, an organic solvent and water are considerable, and among them, water is preferably included.

From the viewpoint of inhibiting contamination of the object to be polished or a function of other components, water that does not contain impurities as much as possible is preferable. Specifically, deionized water, pure water, and the like are preferable. Such water can be obtained by, for example, removing impurity ions with an ion exchange resin, and then removing a foreign material through a filter.

(pH Adjusting Agent)

In the present invention, the pH of the polishing composition is 5.0 or less. When the pH is more than 5.0, there is a possibility that the second layer cannot be selectively polished with respect to the first layer, although the reason is unclear. In the present invention, the upper limit of the pH of the polishing composition is 5.0 or less, preferably 4.5 or less, more preferably 4.4 or less, further preferably 4.3 or less, still more preferably 4.2, still more preferably 4.1 or less, even more preferably 4.0 or less, still more preferably 3.8 or less, still more preferably 3.7 or less, still more preferably 3.6 or less, and still more preferably 3.5 or less. Since the pH of the polishing composition has such an upper limit, the SiOC removal rate can be achieved. In the present invention, the lower limit of the pH of the polishing composition is preferably 1.0 or more, more preferably 1.5 or more, further preferably 1.8 or more, even more preferably 2.0 or more, still more preferably 2.5 or more, and still more preferably 2.7 or more. Since the pH of the polishing composition has such a lower limit, the SiO₂ removal rate can be suppressed.

Specific examples of the pH adjusting agent for adjusting to an acidic region may be either an inorganic compound or an organic compound, but for example, include inorganic acids such as sulfuric acid, nitric acid, boric acid, carbonic acid, hypophosphorous acid, phosphorous acid, and phosphoric acid; and organic acids such as carboxylic acid including citric acid, formic acid, acetic acid, propionic acid, benzoic acid, salicylic acid, glyceric acid, oxalic acid, malonic acid, succinic acid, maleic acid, phthalic acid, malic acid, tartaric acid, and lactic acid, and organic sulfuric acid including methanesulfonic acid, ethanesulfonic acid, and isethionic acid. In addition, in the case of the above-described acid with a valence of 2 or more (for example, sulfuric acid, carbonic acid, phosphoric acid, or oxalic acid), it may be in the form of a salt as long as at least one proton (H′) can be released. Specifically, for example, ammonium hydrogen carbonate or ammonium hydrogen phosphate (the type of the counter cation may be basically anything but a weak base cation (ammonium, triethanol amine, or the like) is preferable) is preferable. In addition, in order to adjust the excessively lowered pH, a pH adjusting agent (for example, ammonia or potassium hydroxide) for adjusting to a basic region may be added.

(Object to be Polished)

In an embodiment of the present invention, the object to be polished has a first layer including a SiO₂ film and a second layer including at least one selected from the group consisting of SiOC, SiOCH, SiCN and SiC (particularly SiOC).

As described above, the present inventors conducted daily research and found that in an object to be polished including the first layer including the SiO₂ film, and the second layer including at least one selected from the group consisting of SiOC, SiOCH, SiCN and SiC, it is desired to selectively polish the second layer with respect to the first layer. In particular, the present inventors found that SiOC and SiO₂ were very close in properties as materials, and thus it was difficult to control a removal rate selectivity.

As a result of intensive studies in view of the above-described problem, the present inventors found that in order to selectively polish the second layer including at least one selected from the group consisting of SiOC, SiOCH, SiCN and SiC with respect to the first layer including the SiO₂ film, it is required to combine the following matters: (i) using a surface-modified abrasive grain in which an organic acid was immobilized on a surface thereof; (ii) adjusting the average primary particle size of the surface-modified abrasive grain to be more than 6 nm to less than 35 nm; and (iii) adjusting the pH to 5.0 or less, in the polishing composition to be used. In the present invention, by cooperatively operating these components, even when materials having extremely close properties are included and the removal rate selectivity is difficult to control, the present inventors succeeded in controlling the removal rate selectivity of the first layer and the second layer. The mechanisms that exert such technical effects are not clear, and in other words, it can be regarded as surprising effects that are unexpected for those skilled in the art. In addition, the polishing composition of the present invention is not required to separately include other compounds such as a polishing inhibitor capable of inhibiting polishing of the first layer, and a polishing accelerator capable of accelerating polishing of the second layer (even though the addition is not limited). That is, the polishing composition of the present invention is also excellent in that the desired technical effect of the present invention can be exhibited by an extremely simple constitution.

In an embodiment of the present invention, the object to be polished further includes a layer including SiN. Since the object to be polished has the layer including SiN, the degree of freedom in designing the semiconductor substrate is improved. In addition, in the embodiment of the present invention, it is preferable to suppress not only the removal rate of the first layer including the SiO₂ film but also the removal rate of the layer including SiN. There is also no particular limitation on the method of suppressing the removal rate of the layer including SiN, but for example, it is preferable to include a SiN inhibitor in the polishing composition. In the present invention, it is also disclosed that the polishing composition does not substantially include the SiN inhibitor. Here, the expression “does not substantially include” means that the content of the SiN inhibitor in the polishing composition is preferably 0.0001 mass % or less.

(Sin Inhibitor)

The SiN inhibitor is not particularly limited, but for example, includes a polymer compound including a sulfo group or a group of salt thereof. Therefore, according to an embodiment of the present invention, the polishing composition further includes the polymer compound including a sulfo group or a group of salt thereof. By such an embodiment, it is possible to suppress the removal rate of the layer including SiN. As the polymer compound including the sulfo group or the salt group thereof, in addition to the compound used in Examples of the present invention, polyvinylsulfonic acid, polystyrenesulfonic acid, polyallylsulfonic acid, polyacrylic acid ethylsulfonic acid, polyacrylic acid butyl sulfonic acid, poly(2-acrylamido-2-methylpropanesulfonic acid), polyisoprenesulfonic acid, and a salt of these acids are preferable. Further, according to the embodiment of the present invention, the lower limit value of the weight average molecular weight of the polymer compound including a sulfo group or a group of salt thereof is not particularly limited, but is preferably 200 or more, more preferably 1,000 or more, further more preferably 10,000 or more, still more preferably 100,000 or more, still more preferably 150,000 or more, and still more preferably 180,000 or more. With such a lower limit value, the desired technical effect of the present invention can be more effectively exhibited. Specifically, the removal rate selectivity of the second layer with respect to the first layer is improved, and the removal rate of the layer including SiN can be more effectively suppressed. In addition, the upper limit value is not particularly limited, but is preferably 1,000,000 or less, more preferably 500,000 or less, further preferably 300,000 or less, and still more preferably 250,000 or less. With such an upper limit value, agglomeration of abrasive grain can be prevented. In addition, as the weight average molecular weight of the polymer compound, a value of the weight average molecular weight (in terms of polyethylene glycol) measured by gel permeation chromatography (GPC) is used. In addition, according to the embodiment of the present invention, pKa of the polymer compound is preferably 1.0 or less, and more preferably 0 or less. With such an embodiment, it is possible to suppress the removal rate of the layer including SiN. In addition, according to the embodiment of the present invention, pKa of the polymer compound is preferably −3.0 or more, more preferably −2.0 or more, and further more preferably −1.7 or more.

In the embodiment of the present invention, the content of the SiN inhibitor in the polishing composition is preferably 0.0008 mass % or more, more preferably 0.0010 mass % or more, and further more preferably 0.0013 mass % or more. With such a lower limit, the desired effect of the present invention can be efficiently exhibited. In the embodiment of the present invention, the content of the SiN inhibitor in the polishing composition is preferably 0.01 mass % or less, more preferably 0.005 mass % or less, further more preferably 0.003 mass % or less, and further more preferably 0.002 mass % or less. With such an upper limit, the desired effect of the present invention can be efficiently exhibited.

(Production Method of Polishing Composition)

In an embodiment of the present invention, there is provided a production method of a polishing composition used for polishing an object to be polished having a first layer including a SiO₂ film, and a second layer including at least one selected from the group consisting of SiOC, SiOCH, SiCN and SiC, and having pH of 5.0 or less, the production method including: mixing a surface-modified abrasive grain in which an organic acid is immobilized on a surface thereof with a dispersing agent, wherein an average primary particle size of the surface-modified abrasive grain is more than 6 nm to less than 35 nm. By such a production method, it is possible to provide a production method of a polishing composition capable of selectively polishing the second layer with respect to the first layer in an object to be polished including the first layer including a SiO₂ film, and the second layer including at least one selected from the group consisting of SiOC, SiOCH, SiCN and SiC.

A specific method of such a production method is not limited, but can be performed by stirring and mixing surface-modified abrasive grain having an organic acid immobilized on the surface and having an average primary particle size of more than 6 nm to less than 35 nm, if necessary, the SiN inhibitor and other components, in the dispersing agent.

For the specific explanation of the surface-modified abrasive grain and the dispersing agent, the above explanation is appropriate. In addition, as other components, components such as a pH adjusting agent, an oxidizing agent, a reducing agent, a surfactant, a water-soluble polymer, and an antifungal agent can be included. A temperature at which each component is mixed is not particularly limited, but preferably 10° C. to 40° C., and heating may be performed to increase a rate of dissolution. In addition, a mixing time is not particularly limited.

(Polishing Method)

In an embodiment of the present invention, there is also provided a polishing method including: preparing an object to be polished having a second layer including at least one selected from the group consisting of SiOC, SiOCH, SiCN and SiC provided on an upper surface of a first layer including a SiO₂ film; and polishing a surface of the object to be polished using the polishing composition of the present invention. By such a polishing method, it is possible to selectively polish the second layer with respect to the first layer in an object to be polished including the first layer including a SiO₂ film, and the second layer including at least one selected from the group consisting of SiOC, SiOCH, SiCN and SiC.

As a polishing apparatus, it is possible to use a general polishing apparatus mounted with a holder for holding a substrate or the like having an object to be polished, a motor capable of changing the rotation speed, or the like and provided with a polishing table to which a polishing pad (polishing cloth) can be attached.

As the polishing pad, general nonwoven fabric, polyurethane, porous fluororesin, and the like can be used without particular limitation. It is preferable that the polishing pad is subjected to groove processing so as to accumulate the polishing composition.

The polishing conditions are also not particularly limited, and for example, the rotation speed of the polishing table is preferably 10 to 500 rpm. The carrier (head) rotation speed is preferably 10 to 500 rpm. The pressure (polishing pressure) applied to the substrate having the object to be polished is preferably 0.1 to 10 psi. A method of supplying the polishing composition to the polishing pad is also not particularly limited, and for example, a method of continuously supplying the polishing composition with a pump or the like is adopted. The supply amount is not limited, but it is preferable that the surface of the polishing pad is always covered with the polishing composition of the present invention.

(Manufacturing Method of Semiconductor Substrate)

In an embodiment of the present invention, there is also provided a manufacturing method of a semiconductor substrate including the above-described polishing method. By such a manufacturing method, it is possible to provide a manufacturing method of a semiconductor substrate using a polishing composition, capable of selectively polishing the second layer with respect to the first layer. Therefore, since the manufacturing method of a semiconductor substrate of the present invention includes the above-described polishing method, the second layer including at least one selected from the group consisting of SiOC, SiOCH, SiCN and SiC may function as, for example, a stopper film, and a semiconductor substrate according to the purpose can be manufactured.

(Method of Improving the Removal Rate of Second Layer Including at Least One Selected from Group Consisting of SiOC, SiOCH, SiCN and SiC and Suppressing Removal Rate of First Layer Including SiO₂ Film)

In the present invention, there is also provided a method of improving the removal rate of the second layer including at least one selected from the group consisting of SiOC, SiOCH, SiCN and SiC and suppressing the removal rate of the first layer including the SiO₂ film, the method including polishing an object to be polished using the polishing composition of the present invention.

(Removal Rate)

In the present invention, the removal rate (Å/min) of the first layer including the SiO₂ film, the removal rate (Å/min) of the second layer including at least one selected from the group consisting of SiOC, SiOCH, SiCN and SiC, and the removal rate (Å/min) of the layer including SiN are preferably 110 (Å/min) or less, 55 (Å/min) or more, and 10 (Å/min) or less, respectively. More preferably, 50 (Å/min) or less, 57 (Å/min) or more, and 5 (Å/min) or less are preferable, respectively.

(Removal Rate Selectivity)

Removal rate selectivity (removal rate ratio) of the removal rate of the second layer with respect to the removal rate of the first layer is preferably 2.3 or more, preferably 3.0 or more, and more preferably 4.0 or more.

Although embodiments of the present invention have been described in detail, they are illustrative and exemplary and not restrictive, and it is obvious that the scope of the present invention should be interpreted by the appended claims. The present invention encompasses the following aspects and modes.

1. A polishing composition used for polishing an object to be polished having a first layer including a SiO₂ film, and a second layer including at least one selected from the group consisting of SiOC, SiOCH, SiCN and SiC, the polishing composition includes: a surface-modified abrasive grain in which an organic acid is immobilized on a surface thereof; and a dispersing agent, wherein an average primary particle size of the surface-modified abrasive grain is more than 6 nm to less than 35 nm, and pH is 5.0 or less.

2. The polishing composition described in 1., further including a polymer compound including a sulfo group or a group of salt thereof.

3. The polishing composition described in 2., wherein the polymer compound has a pKa of 1.0 or less.

4. The polishing composition described in any one of 1. to 3., wherein the object to be polished further has a layer including SiN.

5. A production method of a polishing composition used for polishing an object to be polished having a first layer including a SiO₂ film, and a second layer including at least one selected from the group consisting of SiOC, SiOCH, SiCN and SiC, and having pH of 5.0 or less, the production method including: mixing a surface-modified abrasive grain in which an organic acid is immobilized on a surface thereof with a dispersing agent, wherein an average primary particle size of the surface-modified abrasive grain is more than 6 nm to less than 35 nm.

6. A polishing method including: preparing an object to be polished having a second layer including at least one selected from the group consisting of SiOC, SiOCH, SiCN and SiC provided on an upper surface of a first layer including a SiO₂ film; and polishing a surface of the object to be polished using the polishing composition described in any one of 1. to 5.

7. A manufacturing method of a semiconductor substrate including: the polishing method described in 6.

### Examples

The present invention is described in more detail using the following Examples and Comparative Examples. However, the technical scope of the present invention is not limited to only the following Examples. In addition, unless otherwise specified, “%” and “parts” mean “mass %” and “parts by mass”, respectively.

<Evaluation 1: Dependence on pH>

A polishing composition was prepared by adding 0.3 mass % of colloidal silica (average primary particle size: 14 nm) (abrasive grain type A) in which sulfonic acid was immobilized on a surface thereof with respect to the final polishing composition, and 0.0015 mass % of poly(4-styrenesulfonic acid) ammonium salt with respect to the final polishing composition, respectively, and adding water (deionized water) and the pH adjusting agent so that the pH of the final polishing composition was shown in Table 1. In addition, as the pH adjusting agent, nitric acid was used in Examples 1 to 3 and Comparative Example 1, and ammonia was used in Comparative Example 2. Further, the pH value of the polishing composition (liquid temperature: 25° C.) was confirmed with a pH meter (Model number: LAQUA, manufactured by Horiba Ltd.).

By using each polishing composition, polishing was performed on each of the semiconductor substrates, i.e., the SiOC substrate, the SiO₂ substrate, and the SiN substrate, under the following conditions. Further, SiO₂ in the SiO₂ substrate of the present invention is derived from tetraethyl orthosilicate (TEOS).

(Polishing Apparatus and Polishing Conditions)

Polishing apparatus: FREX 300E manufactured by Ebara Corporation

Polishing pad (nonwoven fabric pad): H800 manufactured by Fujibo Holdings Inc.

Polishing pressure: 2.0 psi (1 psi=6894.76 Pa, hereinafter, the same)

Rotation speed of polishing table: 90 rpm

Rotation speed of head: 91 rpm

Supply of polishing composition: flowing irrigation

Polishing composition flow rate: 300 ml/min

Polishing time: 30 seconds

(Evaluation of Removal Rate (RR))

For each object to be polished, the removal rate was obtained using the following Equation 1. Evaluation results thereof were shown in the following Table 1.

$$[ Mathematical Formula 1 ]$$

$$Removal rate [ Å \text{/} min ] = \frac{\begin{matrix}Film thickness before polishing [ Å ] - \\ Film thickness after polishing [ Å ]\end{matrix}}{Polishing time [ min ]} \qquad ( Equation 1 )$$

The film thickness was measured by a light interference type film thickness measurement apparatus (Model number: ASET-f5x, manufactured by KLA-Tencor Corporation) and evaluated by dividing the difference by the polishing time.

<Evaluation 2: Dependence on Average Primary Particle Size of Abrasive Grain>

Each polishing composition was prepared by changing the average primary particle size of the abrasive grain in Example 1 as shown in Table 2, and the removal rate of each object to be polished was obtained by using each polishing composition in a manner similar to the manner described above.

<Evaluation 3: Dependence on Content of Abrasive Grain>

Each polishing composition was prepared by adjusting the pH to 2.2 by using nitric acid as the pH adjusting agent in Example 1 and changing the content of abrasive grain as shown in Table 3 (Examples 5 to 7). Further, in Comparative Example 4, a polishing composition shown in Comparative Example 5 in which the content of abrasive grain was adjusted as shown in Table 3 was prepared. Thereafter, in a manner similar to the manner described above, the removal rate of each object to be polished was obtained using each polishing composition.

<Evaluation 4: Test of SiN Inhibitor>

Each polishing composition was prepared by changing the type and content of the SiN inhibitor in Example 1 as shown in Table 4. Thereafter, in a manner similar to the manner described above, the removal rate of each object to be polished was obtained using each polishing composition.

Further, in the Examples, the evaluation was performed using each of the SiOC substrate, the SiO₂ substrate, and the SiN substrate. However, it is presumed that the same result as described above can be obtained even in the case of using a substrate having a first layer including a SiO₂ film, and a second layer including at least one selected from the group consisting of SiOC, SiOCH, SiCN and SiC.

TABLE 1
<Evaluation 1>

| | | | | Comparative | Comparative |
|---|---|---|---|---|---|
| Polishing composition | Example 1 | Example 2 | Example 3 | Example 1 | Example 2 |
| pH | 2.0 | 3.1 | 3.9 | 5.8 | 10 |
| Type of abrasive | A | | | | |
| grain/Amount of abrasive | | | | | |
| grain (0.3 [wt %]) | | | | | |
| Average primary particle | 14 | | | | |
| size of abrasive grain [nm] | | | | | |
| SiN inhibitor | Poly(4-styrenesulfonic acid) ammonium salt | | | | |
| | pKa <−1.5 | | | | |
| Molecular weight [—] | 200,000 | | | | |
| Amount of SiN inhibitor | 0.0015 | 0.0015 | 0.0015 | 0.0015 | 0.0015 |
| [wt %] | | | | | |
| SiOC RR [Å/min] | 162 | 88 | 58 | 5 | 2 |
| TEOS RR | 24 | 12 | 8 | 5 | 2 |
| SiN RR | 3 | 4 | 4 | 7 | 5 |
| SiOC/TEOS | 6.8 | 7.3 | 7.3 | 1.0 | 1.0 |
| RR selectivity | | | | | |

TABLE 2
<Evaluation 2>

| | Comparative | | | Comparative |
|---|---|---|---|---|
| Polishing composition | Example 3 | Example 1 | Example 4 | Example 4 |
| Type of abrasive | D | A | B | C |
| grain/Amount of abrasive | | | | |
| grain (0.3[wt %]) | | | | |
| Average primary particle | 6 | 14 | 20 | 35 |
| size of abrasive grain[nm] | | | | |
| pH | 2.0 | | | |
| Molecular weight [—] | 200,000 | | | |
| SiN inhibitor | Poly(4-styrenesulfonic acid) ammonium salt | | | |
| | pKa <−1.5 | | | |
| Amount of SiN inhibitor | 0.0015 | 0.0015 | 0.0015 | 0.0015 |
| [wt %] | | | | |
| SiOC RR | 13 | 162 | 140 | 76 |
| TEOS RR | 30 | 24 | 29 | 35 |
| SiN RR | 3 | 3 | 4 | 4 |
| SiOC/TEOS selectivity | 0.4 | 6.8 | 4.8 | 2.2 |

TABLE 3
<Evaluation 3>

| | | | | Com- | Com- |
|---|---|---|---|---|---|
| | | | | parative | parative |
| Polishing | Exam- | Exam- | Exam- | Exam- | Exam- |
| composition | ple 5 | ple 6 | ple 7 | ple 4 | ple 5 |
| pH | 2.2 | | | 2.0 | |
| Type of abrasive | A | | | C | |
| grain | | | | | |
| Amount of abrasive | 0.3 | 1.3 | 2.6 | 0.3 | 1.3 |
| grain [wt %] | | | | | |
| Average primary | 14 | | | 35 | |
| particle size of | | | | | |
| abrasive grain [nm] | | | | | |
| SiN inhibitor | Poly(4-styrenesulfonic acid) ammonium salt | | | | |
| | pKa < −1.5 | | | | |
| Molecular weight [—] | 200,000 | | | | |
| Amount of SiN | 0.003 | 0.003 | 0.003 | 0.0015 | 0.0015 |
| inhibitor [wt %] | | | | | |
| SiOC RR [Å/min] | 108 | 211 | 281 | 76 | 140 |
| TEOS RR | 22 | 56 | 106 | 35 | 93 |
| SiOC/TEOS RR | 4.9 | 3.8 | 2.7 | 2.2 | 1.5 |
| selectivity | | | | | |

TABLE 4
<Evaluation 4>

| Polishing | | | | Example |
|---|---|---|---|---|
| composition | Example 1 | Example 8 | Example 9 | 10 |
| Type of abrasive | A | | | |
| grain/Amount of | | | | |
| abrasive grain | | | | |
| (0.3 [wt %]) | | | | |
| pH | 2.0 | | | |
| SiN inhibitor | Poly(4-styrenesulfonic | Triethanolamine | Polynaphthalenesulfonate | — |
| | acid) | polyoxyethylene | (condensate of | |
| | ammonium salt | allylphenyl ether | 2-naphthalenesulfonic | |
| | pKa <−1.5 | phosphate | acid) | |
| | | pKa ≈ 2.0 | pKa <−1.8 | |
| Molecular weight [—] | 200,000 | 1,500 | 261.53 | |
| Amount of SiN | 0.0015 | 0.0020 | 0.0030 | — |
| inhibitor [wt %] | | | | |
| SiOC | 162 | 210 | 91 | 206 |
| TEOS | 24 | 31 | 22 | 20 |
| SiN | 3 | 290 | 1 | 332 |
| SiOC/TEOS | 6.8 | 6.8 | 4.1 | 10 |
| selectivity | | | | |

What is claimed is:

1. A polishing composition used for polishing an object to be polished having a first layer including a SiO₂ film, and a second layer including at least one selected from the group consisting of SiOC, SiOCH, SiCN and SiC, the polishing composition comprises:
a surface-modified abrasive grain in which an organic acid is immobilized on a surface thereof; and a dispersing agent,
wherein an average primary particle size of the surface-modified abrasive grain is more than 6 nm to less than 35 nm, and
pH is 5.0 or less.

2. The polishing composition according to claim 1, further comprising a polymer compound including a sulfo group or a group of salt thereof.

3. The polishing composition according to claim 2, wherein the polymer compound has a pKa of 1.0 or less.

4. The polishing composition according to claim 1, wherein the object to be polished further has a layer including SiN.

5. A production method of a polishing composition used for polishing an object to be polished having a first layer including a SiO₂ film, and a second layer including at least one selected from the group consisting of SiOC, SiOCH, SiCN and SiC, and having pH of 5.0 or less, the production method comprising:
mixing a surface-modified abrasive grain in which an organic acid is immobilized on a surface thereof with a dispersing agent,
wherein an average primary particle size of the surface-modified abrasive grain is more than 6 nm to less than 35 nm.

6. A polishing method comprising:
preparing an object to be polished having a second layer including at least one selected from the group consisting of SiOC, SiOCH, SiCN and SiC provided on an upper surface of a first layer including a SiO₂ film; and
polishing a surface of the object to be polished using the polishing composition according to claim 1.

7. A manufacturing method of a semiconductor substrate, comprising:
the polishing method according to claim 6.
